(19) United States
(12) Patent Application Publication
(10) Pub. No.: US 2021/0396472 A1
(43) Pub. Date: Dec. 23, 2021

(54) HEATING DEVICE WITH HEAT CONDUCTING ELEMENT AND EVAPORATION SYSTEM USING SAME

(71) Applicant: SYSKEY TECHNOLOGY CO., LTD., Hsinchu County (TW)

(72) Inventor: Hsueh-Hsien Wu, Hsinchu City (TW)

(21) Appl. No.: 17/020,772

(22) Filed: Sep. 14, 2020

(30) Foreign Application Priority Data
Jun. 18, 2020 (TW) 109120539

(51) Int. Cl. F27B 14/14; F27B 14/20; F27B 14/10; F27B 14/08

(52) U.S. Cl. CPC F27B 14/14; F27B 2014/0831; F27B 14/10; F27B 14/20

(57) ABSTRACT

A heating device with a heat conducting element and an evaporation system using the same are provided. The heating device includes a crucible, a heat conducting element and a heating element. The crucible includes a bottom surface, an opening opposite to the bottom surface and an accommodation space for accommodating a to-be-evaporated material. The heat conducting element is disposed in the accommodation space of the crucible and disposed on the bottom surface and extending towards the opening. The heating element is disposed adjacent to the crucible.

### BACKGROUND OF THE INVENTION

### 1. Field of the Invention

The present invention relates to a heating device and an evaporation system using the same, and more particularly to a heating device including a heat conducting element and an evaporation system using the same.

### 2. Description of the Prior Art

The evaporation process is a widely used coating technology. In prior art, a common method is using an evaporation machine to heat the material which is to be evaporated in a thermal evaporation chamber, so that the material is evaporated and dispersed in the chamber, and then attached to the to-be-coated object to form a coating on the surface of the to-be-coated object.

However, when the material is heated, the part of the material adjacent to the heating source is easier to be heated to evaporate, and the part of the material relatively away from the heating source is less easily heated, which may cause the evaporation state of the material to be unstable due to uneven heating, thus affecting the evaporation rate and resulting in poor coating quality. This condition is more obvious in materials with poor thermal conductivity. It is difficult for the materials with poor thermal conductivity to conduct heat from the part adjacent to the heating source to the part away from the heating source. Therefore, it is more difficult to control the evaporation state and the evaporation rate, and the accuracy and the stability of the evaporation process are affected severely.

### SUMMARY OF THE INVENTION

One of the objectives of the present invention is to provide a heating device and an evaporation system using the same, and the heating device includes a heat conducting element, which may improve the problems of uneven heating of materials during heating, make the evaporation rate more stable, and further improve the quality of coating.

An embodiment of the present invention provides a heating device used in an evaporation system. The heating device includes a crucible, a heat conducting element and a heating element. The crucible includes a bottom surface, an opening opposite to the bottom surface and an accommodation space for accommodating a to-be-evaporated material. The heat conducting element is disposed in the accommodation space of the crucible and disposed on the bottom surface and extending towards the opening. The heating element is disposed adjacent to the crucible.

An embodiment of the present invention provides an evaporation system. The evaporation system includes a chamber, at least one heating device and at least one crystal sensor. The at least one heating device is disposed in the chamber, and each of the at least one heating device includes a crucible, a heat conducting element and a heating element. The crucible includes a bottom surface, an opening opposite to the bottom surface and an accommodation space for accommodating a to-be-evaporated material. The heat conducting element is disposed in the accommodation space of the crucible and disposed on the bottom surface and extending towards the opening. The heating element is disposed adjacent to the crucible. The crystal sensor is disposed in the chamber and corresponding to the heating device.

According to a heating device with a heat conducting element and an evaporation system using the same of the present invention, by disposing the heat conducting element in the crucible, the to-be-evaporated material may be heated and evaporated uniformly, and the evaporation rate may be more stable. Thus, the accuracy, the stability and the coating quality of the evaporation may be increased. In addition, for the to-be-evaporated material with poor thermal conductivity, through the disposing of the heat conducting element, the to-be-evaporated material may be uniformly heated from the part close to the sidewall of the crucible to the part at the center of the crucible, so that the stability of the evaporation rate may be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional-view schematic diagram of a heating device according to an embodiment of the present invention.

FIG. 2 is a schematic diagram of heating a to-be evaporated material by a heating device according to an embodiment of the present invention.

FIG. 3 is a partial sectional-view schematic diagram of an evaporation system according to an embodiment of the present invention.

FIG. 4A is a schematic diagram of the evaporation rate of an evaporation system without a heat conducting element in a heating device.

FIG. 4B is a schematic diagram of the evaporation rate of an evaporation system with a heat conducting element in a heating device.

### DETAILED DESCRIPTION

The present disclosure may be understood by reference to the following detailed description, taken in conjunction with the drawings as described below. It is noted that, for purposes of illustrative clarity and being easily understood by the readers, various drawings of the present invention show at least a portion of the heating device or at least a portion of the evaporation system, and certain elements in various drawings may not be drawn to scale. In addition, the number and dimension of each element shown in drawings are only illustrative and are not intended to limit the scope of the present invention.

Certain terms are used throughout the description and following claims of the present invention to refer to particular components. As one skilled in the art will understand, evaporation system manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. When the terms “include”, “comprise” and/or “have” are used in the description of the present invention, the existence of corresponding features, regions, steps, operations and/or components would be specified, but not excluding the existence or addition of one or more other features, regions, steps, operations, components and/or combinations thereof.

When an element or layer is referred to as being “on” or “connected to” another element or layer, it may be directly on or directly connected to the other element or layer, or intervening elements or layers may be presented. In contrast, when an element is referred to as being “directly on” or “directly connected to” another element or layer, there are no intervening elements or layers presented.

It should be noted that the technical features in different embodiments described in the following can be replaced, recombined, or mixed with one another to constitute another embodiment without departing from the spirit of the present disclosure.

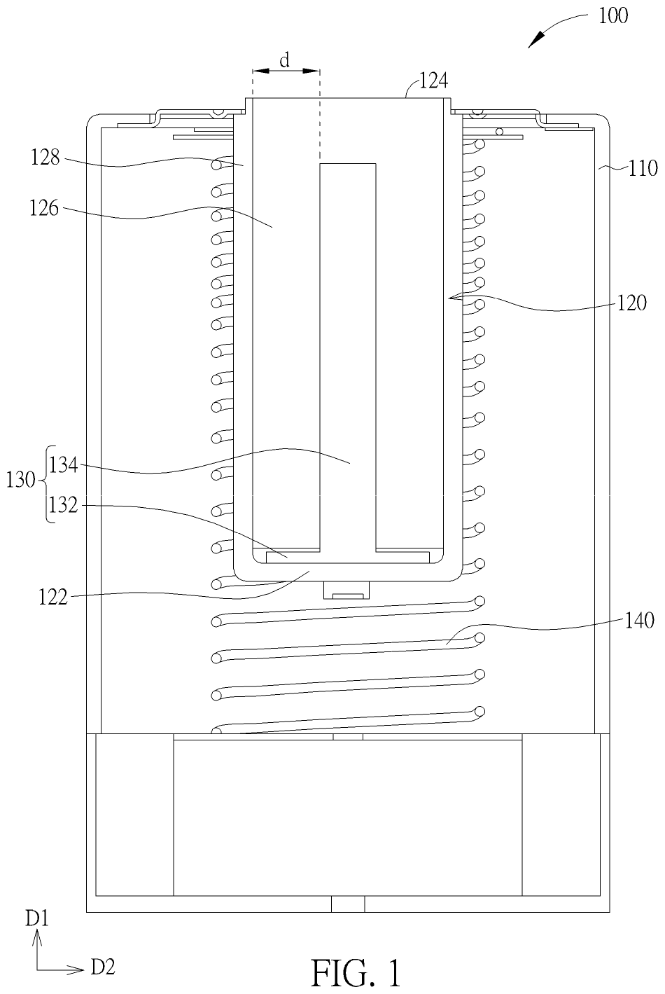

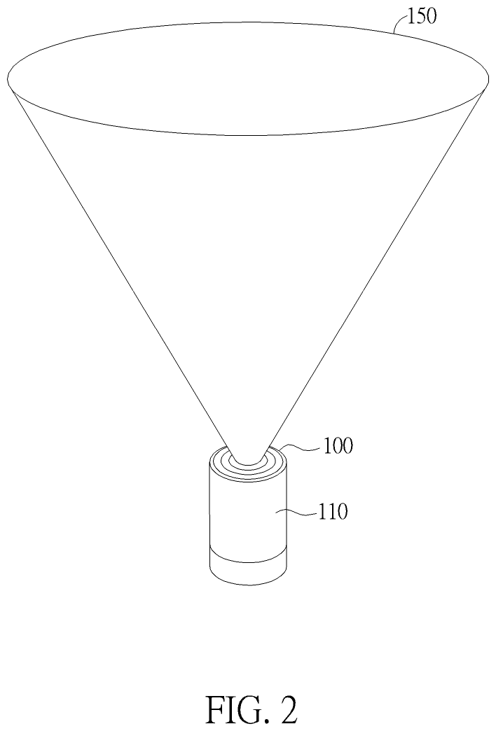

Please refer to FIG. 1 and FIG. 2. FIG. 1 is a sectional-view schematic diagram of a heating device according to an embodiment of the present invention. FIG. 2 is a schematic diagram of heating a to-be evaporated material by a heating device according to an embodiment of the present invention. As shown in FIG. 1 and FIG. 2, the heating device 100 of an embodiment of the present invention may be used in an evaporation system such as (but not limited to) a thermal evaporation coater, and the heating device 100 may be, for example, served as a heater cell of an evaporation source, but not limited thereto. The heating device 100 includes a crucible 120, a heat conducting element 130 and a heating element 140, and the crucible 120, the heat conducting element 130 and the heating element 140 are disposed in a housing 110. The housing 110 may be included in the heating device 100, and may be a cylindrical housing for example. The axial direction of the cylindrical housing may be a first direction D1 along the vertical direction, and the radial direction of the cylindrical housing may be a second direction D2 along the horizontal direction, but not limited thereto. The crucible 120 includes a bottom surface 122, an opening 124 and an accommodation space 126. The opening 124 is opposite to the bottom surface 122, and the accommodation space 126 is used for accommodating a to-be-evaporated material 150. The heat conducting element 130 is disposed in the accommodation space 126 of the crucible 120, and the heat conducting element 130 is disposed on the bottom surface 122 of the crucible 120 and extends towards the opening 124 of the crucible 120. For example, the heat conducting element 130 may extend from the bottom surface 122 of the crucible 120 to the opening 124 of the crucible 120 substantially along the first direction D1, but not limited thereto.

The heating element 140 is disposed adjacent to the crucible 120, and the heating element may be, for example, a heating coil surrounding the crucible 120, but not limited thereto. The heating element 140 may be used for heating the crucible 120, so that the to-be-evaporated material 150 accommodated in the accommodation space 126 of the crucible 120 is evaporated from the opening 124 of the crucible 120 after being heated, thereby being evaporated and dispersed into the chamber of the evaporation system by the heating device 100. The to-be-evaporated material 150 may be evaporated and dispersed into the chamber of the evaporation system by the heating device 100 in a sectorial evaporation scattering angle or an irregular shape evaporation scattering angle, as shown in FIG. 2, but not limited thereto.

The heat conducting element 130 may include metal material or alloy material, for example including copper, aluminum, steel, stainless steel or other suitable metals or alloys, or the heat conducting element 130 may further include other materials with good thermal conductivity, but not limited thereto. In some embodiments, the heat conducting element 130 may include a base 132 and an extension portion 134. The base 132 is disposed on the bottom surface 122 of the crucible 120, and the extension portion 134 extends from the base 132 and extends towards the opening 124 of the crucible 120 along the first direction D1, wherein the extension portion 134 may be, for example, rod-shaped, strip-shaped, net-shaped or other suitable shapes.

The to-be-evaporated material 150 may, for example, include methylammonium iodide (MAI), formamidinium iodide (FAI) or phenethylammonium iodide (PEAI). Since the thermal conductivity of these materials are poor, through the heat conducting element 130 disposed in the crucible 120, the performance of thermal conductivity may be improved. Therefore, besides the part of the to-be-evaporated material 150 that is close to the heating element 140, the part of the to-be-evaporated material 150 that is relatively away from the heating element 140 may also be heated and evaporated. That is to say, the to-be-evaporated material 150 may be integrally and uniformly heated and evaporated, so that the evaporation rate may be relatively stable, thereby improving the accuracy, stability and coating quality of the evaporation.

The crucible 120 may further include a sidewall 128 surrounding the heat conducting element 130, and the sidewall 128, the bottom surface 122 and the opening 124 define the accommodation space 126 in common. Furthermore, at least one interval d exists between the heat conducting element 130 and the sidewall 128 of the crucible 120. For example, the interval d is the distance along the second direction D2 between the surface of the heat conducting element 130 and the sidewall 128 of the crucible 120. In some embodiments, the heat conducting element 130 may be disposed at a center of the crucible 120. For example, the heat conducting element 130 may be disposed on the center of the bottom surface 122 of the crucible 120, or the central axis of the extension portion 134 of the heat conducting element 130 may pass through the center of the bottom surface 122 of the crucible 120, but not limited thereto. In addition, in some embodiments, the intervals d between each part of the heat conducting element 130 and the sidewall 128 of the crucible 120 are equal, that is, the distances along the second direction D2 between the surfaces of each part of the heat conducting element 130 and the sidewall 128 of the crucible 120 are equal. Through the position configuration of the heat conducting element 130, the to-be-evaporated material 150 may be uniformly heated from the part close to the sidewall 128 of the crucible 120 to the part at the center of the crucible 120, so that the stability of the evaporation rate may be improved.

In the design of the element configuration, the size of the heat conducting element 130 may be changed with the size of the crucible 120. For example, the diameter of the heat conducting element 130 is less than the diameter of the crucible 120. In some embodiments, the height of the heat conducting element 130 is less than or equal to the height of the crucible 120. That is to say, the height reached by the heat conducting element 130 extending along the first direction D1 is less than or equal to the height of the opening 124 of the crucible 120. Through the configuration describe above, the height of the heat conducting element 130 is less than or equal to the height of the heating element 140, and thus the heat provided by the heating element 140 may be better absorbed by the heat conducting element 130, so as to achieve better heat absorbing and heat conducting performance.

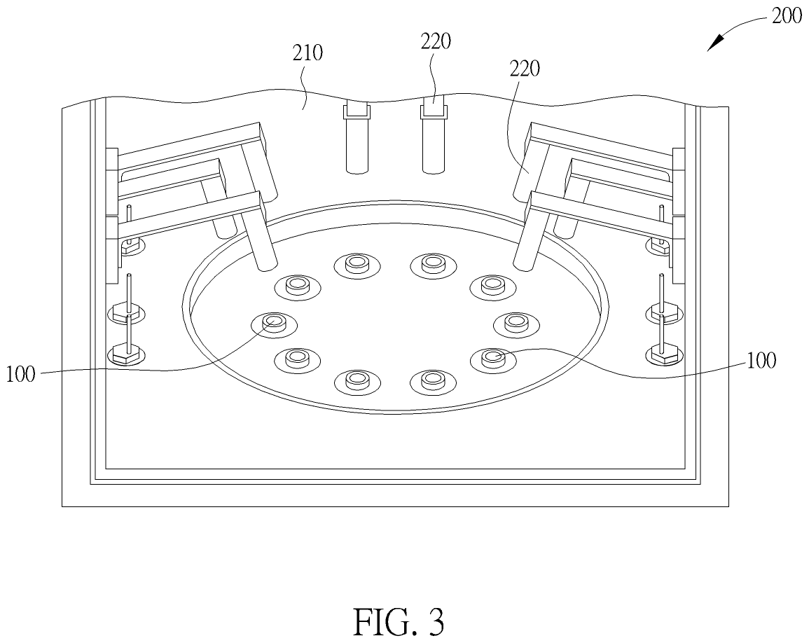

Please refer to FIG. 3 and also refer to FIG. 1 and FIG. 2. FIG. 3 is a partial sectional-view schematic diagram of an evaporation system according to an embodiment of the present invention, wherein only a part of elements in the evaporation system are shown for simplifying illustration, and the other elements (e.g., a bearing device for bearing the to-be-coated object) are omitted. As shown in FIG. 1, FIG. 2 and FIG. 3, an evaporation system 200 of an embodiment of the present invention includes a chamber 210, at least one heating device 100 and at least one crystal sensor 220. The evaporation system 200 may be, for example (but not limited to), a thermal evaporation coater, and the heating device 100 may be, for example, a heater cell of the thermal evaporation coater, but not limited thereto. In FIG. 3, the evaporation system 200 includes a plurality of heating devices 100 disposed in the chamber 210, for example disposed at the bottom of the chamber 210. Each of the heating devices 100 may include a housing 110, a crucible 120, a heat conducting element 130 and a heating element 140, and the crucible 120, the heat conducting element 130 and the heating element 140 are disposed in the housing 110. The crucible 120 includes a bottom surface, 122 an opening 124 and an accommodation space 126. The opening 124 is opposite to the bottom surface 122, and the accommodation space 126 is used for accommodating a to-be-evaporated material 150. The heat conducting element 130 is disposed in the accommodation space 126 of the crucible 120, and the heat conducting element 130 is disposed on the bottom surface 122 of the crucible 120 and extends towards the opening 124 of the crucible. The heating element 140 is disposed adjacent to the crucible 120, and the heating element 140 may be, for example, a heating coil surrounding the crucible 120. The crystal sensors 220 are disposed in the chamber 210 and correspond to the heating devices 100, and the crystal sensors 220 are disposed above the heating devices 100 for sensing the evaporation rate, for example, the number of atoms evaporated per second (atom/second, A/s). In some embodiments, the crystal sensors 220 are disposed one-to-one corresponding to the heating devices 100, that is, the number of the crystal sensors 220 is equal to the number of the heating devices 100, so that the evaporation rate of each of the heating devices 100 may be respectively sensed by each of the crystal sensors 220, but not limited thereto. The detailed elements, structures, sizes and materials included in the heating device 100 of the evaporation system 200 of the present invention are illustrated in detail in the embodiments described above, and will not be described redundantly herein.

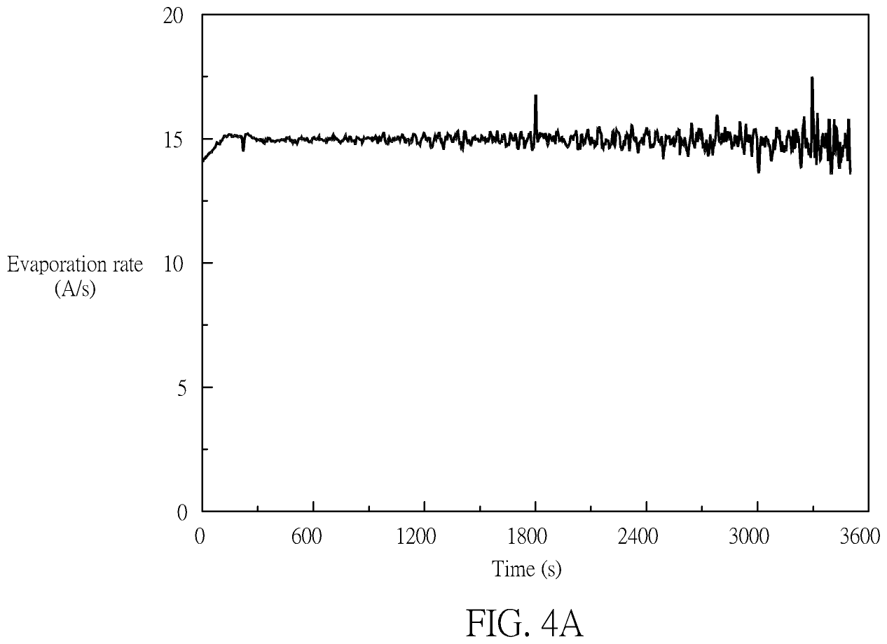

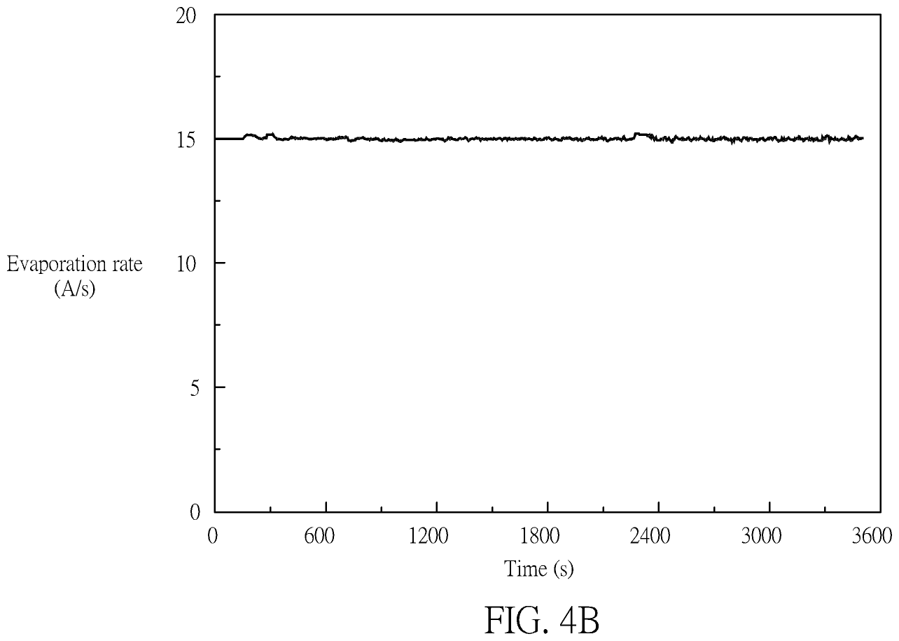

Please refer to FIG. 4A and FIG. 4B. FIG. 4A is a schematic diagram of the evaporation rate of an evaporation system without a heat conducting element in a heating device. FIG. 4B is a schematic diagram of the evaporation rate of an evaporation system with a heat conducting element in a heating device. As shown in FIG. 4A, in the condition that the heat conducting element does not exist in the heating device, the fluctuation range of the evaporation rate sensed by the crystal sensor is great and unstable, which leads to poor coating quality. As shown in FIG. 4B, in the condition that the heat conducting element exists in the heating device, since the disposing of the heat conducting element may make the to-be-evaporated material be uniformly heated and evaporated, the fluctuation range of the evaporation rate sensed by the crystal sensor is small and stable, so that good coating quality may be obtained.

From the description above, according to the heating device with the heat conducting element and the evaporation system using the same of the present invention, by disposing the heat conducting element in the crucible, the to-be-evaporated material may be heated and evaporated uniformly, and the evaporation rate may be more stable. Thus, the accuracy, the stability and the coating quality of the evaporation may be increased. In addition, for the to-be-evaporated material with poor thermal conductivity, through the disposing of the heat conducting element, the to-be-evaporated material may be uniformly heated from the part close to the sidewall of the crucible to the part at the center of the crucible, so that the stability of the evaporation rate may be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A heating device, used in an evaporation system, comprising:
a crucible, comprising:
a bottom surface;
an opening opposite to the bottom surface; and
an accommodation space for accommodating a to-be-evaporated material;
a heat conducting element disposed in the accommodation space of the crucible, and disposed on the bottom surface and extending towards the opening; and
a heating element disposed adjacent to the crucible.

2. The heating device according to claim 1, wherein the heat conducting element comprises metal material or alloy material.

3. The heating device according to claim 1, wherein the to-be-evaporated material comprises methylammonium iodide (MAI), formamidinium iodide (FAI) or phenethylammonium iodide (PEAI).

4. The heating device according to claim 1, wherein the crucible comprises a sidewall surrounding the heat conducting element, and at least one interval exists between the heat conducting element and the sidewall of the crucible.

5. The heating device according to claim 4, wherein the heat conducting element is disposed at a center of the crucible, and the intervals between each part of the heat conducting element and the sidewall of the crucible are equal.

6. The heating device according to claim 1, wherein a height of the heat conducting element is less than or equal to a height of the crucible.

7. The heating device according to claim 6, wherein the heating element disposed around the crucible, and the height of the heat conducting element is less than or equal to a height of the heating element.

8. An evaporation system, comprising:
a chamber;
at least one heating device disposed in the chamber, wherein each of the at least one heating device comprises:
a crucible comprising a bottom surface, an opening opposite to the bottom surface and an accommodation space for accommodating a to-be-evaporated material;
a heat conducting element disposed in the accommodation space of the crucible, and disposed on the bottom surface and extending towards the opening; and
a heating element disposed adjacent to the crucible; and
at least one crystal sensor disposed in the chamber and corresponding to the heating device.

9. The evaporation system according to claim 8, wherein the heat conducting element comprises metal material or alloy material, and the to-be-evaporated material comprises methylammonium iodide, formamidinium iodide or phenethylammonium iodide.

10. The evaporation system according to claim 8, wherein the heat conducting element is disposed at a center of the crucible.
